(19) United States
(12) Patent Application Publication
(10) Pub. No.: US 2026/0047063 A1
(43) Pub. Date: Feb. 12, 2026

(54) SEMICONDUCTOR DEVICE AND METHOD FOR FABRICATING THE SAME

(71) Applicant: SK hynix Inc., Gyeonggi-do (KR)

(72) Inventors: Jaesuk CHOI, Gyeonggi-do (KR); Beomyoung KIM, Gyeonggi-do (KR); Kyung Sun RYU, Gyeonggi-do (KR)

(21) Appl. No.: 19/182,600

(22) Filed: Apr. 18, 2025

(30) Foreign Application Priority Data
Aug. 6, 2024 (KR) 10-2024-0104512

(51) Int. Cl. H10B 12/00; H10D 1/68

(52) U.S. Cl. CPC H10B 12/033; H10B 12/315; H10D 1/711

(57) ABSTRACT

A method for fabricating a semiconductor device includes forming a mold stack including mold layers and a lower supporter layer over a substrate; forming lower electrodes having lower and upper portions in the mold stack; exposing the lower electrodes by recessing an upper surface of the mold stack; forming trimmed portions by trimming the exposed upper portions of the lower electrodes; forming a pyrolytic layer surrounding lower sides of the trimmed portions; forming a supporter liner layer over the pyrolytic layer and the trimmed portions; forming a horizontal level gap by removing the pyrolytic layer; forming an upper supporter layer over the supporter liner layer; forming a supporter hole by etching the upper supporter layer and the supporter liner layer; and exposing the outer walls of the lower portions of the lower electrodes by removing the mold layers through the supporter hole and the horizontal level gap.

### CROSS-REFERENCE TO RELATED APPLICATIONS

The present application claims priority under 35 U.S. C 119(a) to Korean Patent Application No. 10-2024-0104512, filed on Aug. 6, 2024, which is incorporated herein by reference in its entirety.

### BACKGROUND

### 1. Field

Embodiments of the present disclosure relate to a semiconductor device and a method for fabricating the same, and more particularly, to a semiconductor device including a capacitor, and a method for fabricating the semiconductor device.

### 2. Description of the Related Art

Recently, as the aspect ratio of capacitors is increasing, supporters are being applied to prevent the capacitors from collapsing. However, there is an issue in that the process difficulty is increasing due to the difference between the etching selectivity of a mold layer and the etching selectivity of a supporter and the increase in the height that may be caused due to the application of supporters.

### SUMMARY

Embodiments of the present disclosure are directed to reducing the process difficulty in making capacitors with higher aspect ratio, increased capacitance, and higher structural stability.

Embodiments of the present disclosure are directed to forming a capacitor with higher aspect ratio and improved capacitance and structural stability by applying an upper supporter after a lower electrode is formed.

In particular a pyrolytic polymer may be employed for the making of the upper supporter.

In accordance with an embodiment of the present disclosure, a method for fabricating a semiconductor device includes forming a mold stack including a plurality of mold layers and a lower supporter layer over a substrate; forming a plurality of lower electrodes having lower portions and upper portions in the mold stack; exposing the upper portions of the lower electrodes by recessing an upper surface of the mold stack; forming trimmed portions by trimming the exposed upper portions of the lower electrodes; forming a pyrolytic layer surrounding lower sides of the trimmed portions; forming a supporter liner layer over the pyrolytic layer and the trimmed portions; forming a horizontal level gap exposing outer walls of the trimmed portions by removing the pyrolytic layer; forming an upper supporter layer over the supporter liner layer; forming a supporter hole exposing the horizontal level gap by etching the upper supporter layer and the supporter liner layer; and exposing the outer walls of the lower portions of the lower electrodes by removing the mold layers through the supporter hole and the horizontal level gap.

In accordance with another embodiment of the present disclosure, a semiconductor device includes an array of lower electrodes each including a first pillar portion and a second pillar portion which is disposed over the first pillar portion and having a narrower line width than the first pillar portion; a lower supporter suitable for supporting outer walls of the first pillar portions of the lower electrodes; an upper supporter suitable for supporting upper portions and outer walls of the second pillar portions of the lower electrodes; a dielectric layer suitable for covering the lower electrodes, the lower supporter, and the upper supporter; and an upper electrode over the dielectric layer.

In accordance with another embodiment of the present disclosure, a semiconductor device includes an array of lower electrodes each including a non-trimmed portion and a trimmed portion having a narrower line width than the non-trimmed portion; a lower supporter suitable for supporting outer walls of the non-trimmed portions of the lower electrodes; an upper supporter suitable for supporting a portion of a side wall and an upper portion of each of the trimmed portions of the lower electrodes; a dielectric layer suitable for covering the lower electrodes, the lower supporter, and the upper supporter; and an upper electrode over the dielectric layer.

In accordance with another embodiment of the present disclosure, a semiconductor device includes an array of lower electrodes each including a first pillar portion and a second pillar portion disposed over the first pillar portion and having a narrower line width than the first pillar portion; a lower supporter suitable for supporting outer walls of the first pillar portions of the lower electrodes; an upper supporter suitable for supporting upper portions and outer walls of the second pillar portions of the lower electrodes; and a supporter liner between the upper supporter and the second pillar portions.

In accordance with another embodiment of the present disclosure, a semiconductor device includes an array of pillar-shaped electrodes each including a first pillar portion and a second pillar portion disposed over the first pillar portion and having a narrower line width than the first pillar portion; a lower supporter suitable for supporting outer walls of the first pillar portions of the pillar-shaped electrodes; and an upper supporter suitable for supporting upper portions and outer walls of the second pillar portions of the pillar-shaped electrodes.

In accordance with another embodiment of the present disclosure, a method for fabricating a semiconductor device includes forming a mold stack including a lower supporter layer over a substrate; forming a lower electrode in the mold stack; exposing an upper portion of the lower electrode; trimming the exposed upper portion of the lower electrodes to form a trimmed portion of the lower electrode exposed over the mold stack; surrounding lower sides of the trimmed portion with a pyrolytic layer; forming a supporter liner layer surrounding a top surface of the trimmed portion of the lower electrode and the pyrolytic layer; and forming an upper supporter layer over the supporter liner layer.

These and other features and advantages of the embodiments of the present disclosure will become better understood by those with ordinary skill in the art from the following drawings and detailed description.

### BRIEF DESCRIPTION OF THE DRAWINGS

FIG. 1 is a cross-sectional view illustrating a semiconductor device in accordance with an embodiment of the present disclosure.

FIGS. 2A to 2P are process cross-sectional views illustrating a method for fabricating a semiconductor device in accordance with an embodiment of the present disclosure.

### DETAILED DESCRIPTION

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure is thorough and conveys the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Features described with respect to one embodiment may also be combined with features of another embodiment.

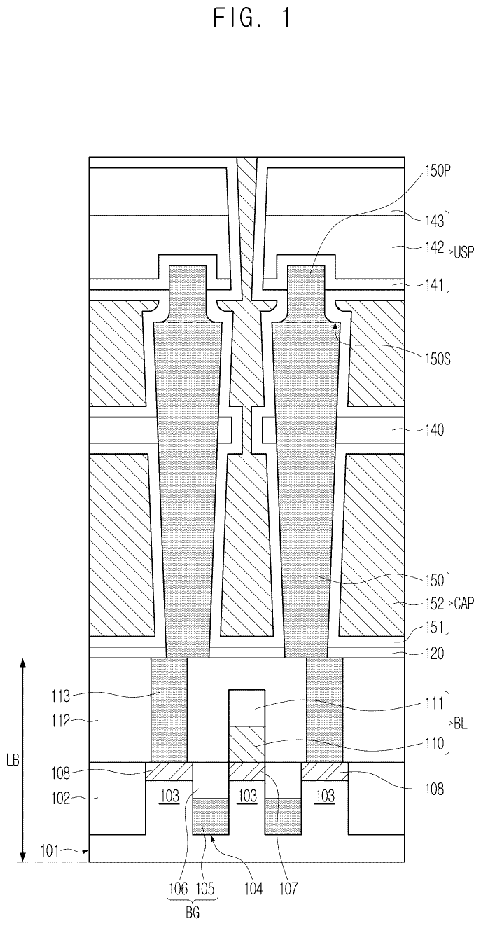

FIG. 1 is a cross-sectional view illustrating a semiconductor device in accordance with an embodiment of the present disclosure.

Referring to FIG. 1, a semiconductor device may include a capacitor CAP which is disposed over a substrate 101 including a lower structure LB.

The lower structure LB may include a gate structure BG disposed in the substrate 101, and a bit line BL and a storage node contact 113 disposed over the substrate 101.

The substrate 101 may be a material appropriate for semiconductor processing. The substrate 101 may include a semiconductor substrate. The substrate 101 may be formed of a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include another semiconductor material, such as germanium. The substrate 101 may include a III/V-group semiconductor substrate, for example, a compound semiconductor substrate, such as gallium arsenide (GaAs). The substrate 101 may include an SOI (Silicon-On-Insulator) substrate.

An isolation layer 102 and an active region 103 may be formed over the substrate 101. A plurality of active regions 103 may be defined by the isolation layer 102.

A gate structure BG may be disposed in the substrate 101. The gate structure BG may include a buried gate structure disposed at a lower level than the upper surface of the substrate 101. Although FIG. 1 illustrates a buried gate structure disposed at a lower level than the upper surface of the substrate 101, the technical concepts and scope of the present disclosure are not limited thereto, and all gate structures including a recess gate, a fin gate, a planar gate, and the like may be applied.

The gate structure BG may include a stacked structure of a gate electrode 105 and a gate capping layer 106 that gap-fills the gate trench 104. A gate dielectric layer may be interposed between the gate trench 104 and the stacked structure of the gate electrode 105 and the gate capping layer 106.

To be specific, the gate trench 104 may be formed in the substrate 101. The bottom surface of the gate trench 104 may be disposed at a higher level than the bottom surface of the isolation layer 102. The gate trench 104 may have a shallower depth than the isolation layer 102. According to another embodiment of the present disclosure, the bottom portion of the gate trench 104 may have a curvature. According to another embodiment of the present disclosure, the isolation layer 102 of a direction in which the gate trench 104 extends may be etched to a predetermined depth to form a fin in the active region 103.

The gate electrode 105 may fill a portion of the gate trench 104. The gate capping layer 106 may fill the remaining portion of the gate trench 104 over the gate electrode 105. The upper surface of the gate capping layer 106 may be disposed at the same level as the upper surface of the substrate 101.

First and second impurity regions 107 and 108 may be formed in the substrate 101. The first and second impurity regions 107 and 108 may be respectively referred to as ‘first and second source/drain regions’. The first and second impurity regions 107 and 108 may be spaced apart from each other by the gate trench 104. As a result, the gate electrode 105 and the first and second impurity regions 107 and 108 may become a cell transistor. The cell transistor may increase the channel length by forming the gate electrode 105 in a buried gate structure, thereby improving a short channel effect.

An inter-layer dielectric layer 112 may be disposed over the substrate 101. For example, the inter-layer dielectric layer 112 may include at least one of silicon nitride, silicon oxide, and silicon oxynitride. According to another embodiment of the present disclosure, the inter-layer dielectric layer 112 may include an empty space.

A bit line structure BL and a storage node contact 113 may be disposed in the inter-layer dielectric layer 112. The bit line structure BL may be formed to be coupled to the first source/drain region 107 between the gate structures BG.

The storage node contact 113 may penetrate the inter-layer dielectric layer 112. A first end of the storage node contact 113 may contact the substrate 101, and a second end of the storage node contact 113 may contact a lower electrode 150. The storage node contact 113 may be coupled to the second source/drain region 107 of the substrate 101. The storage node contact 113 and the lower electrode 150 may overlap with each other at least partially.

An etch stop pattern 120 may be disposed over the lower structure LB. The etch stop pattern 120 may include a dielectric material. For example, the etch stop pattern 120 may include silicon nitride, however the technical concepts and scope of the present disclosure are not limited thereto.

The lower electrodes 150 may be disposed over the lower structure LB. The lower electrodes 150 may penetrate the etch stop pattern 120. Each lower electrode 150 may be electrically connected to the substrate 101 by the storage node contact 113 that is formed in the lower structure LB. The lower electrode 150 may have a high aspect ratio. Here, the aspect ratio may refer to a ratio of height to width. According to an embodiment of the present disclosure, the high aspect ratio may refer to an aspect ratio of approximately 10:1 or more. The height of the lower electrode 150 may be approximately 5000 Å or more. For example, each lower electrode 150 may have a pillar shape. According to another embodiment of the present disclosure, each lower electrode 150 may have a cylindrical shape or a pylinder shape in which a first lower electrode having a cylindrical shape and a second lower electrode gap-filling the first lower electrode are combined.

Each lower electrode 150 may include a conductive material. For example, each lower electrode 150 may include cobalt (Co), titanium (Ti), nickel (Ni), tungsten (W), molybdenum (Mo), gold (Pt), ruthenium (Ru), iridium (Ir), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), tungsten nitride (WN), or a combination thereof. According to an embodiment of the present disclosure, each lower electrode 150 may be formed of titanium nitride. According to another embodiment of the present disclosure, the lower electrode 150 may include a stacked structure of TiSiN/TiN.

According to another embodiment of the present disclosure, each lower electrode 150 may include a stacked structure of titanium nitride having a cylinder shape and titanium silicon nitride gap-filling the inside of the cylinder shape.

Each lower electrode 150 may include a trimmed portion 150P. The trimmed portion 150P may be referred to as an ‘upper portion’. The lower electrode 150 excluding the trimmed portion 150P may be referred to as a non-trimmed portion. The non-trimmed portion may be referred to as a ‘lower portion’. The non-trimmed portion of the lower electrode 150 may be referred to as a ‘first pillar portion’, and the trimmed portion 150P of the lower electrode may be referred to as a ‘second pillar portion’.

According to an embodiment, the trimmed portion 150P may have uniform line widths at the top and bottom. The trimmed portion 150P may have a side which is perpendicular to the surface of the substrate 101. The non-trimmed portion may have a line width that decreases as it goes from top to bottom. The non-trimmed portion may have a side of a negative slope.

The trimmed portion 150P may refer to an area having a narrower line width than the non-trimmed portion due to the trimming process. The side wall of the trimmed portion 150P may be continuous with the non-trimmed portion to form an integrated structure.

The upper surface (e.g., the top surface) of the non-trimmed portion, which is exposed in a direction parallel to the surface of the substrate 101 due to the line width difference between the trimmed portion 150P and the non-trimmed portion, may be referred to as a ‘shoulder portion 150S’. The shoulder portion 150S may have a shape that surrounds the trimmed portion 150P on a plane. The connecting portion between the shoulder portion 150S and the trimmed portion 150P may be rounded. The line width of the shoulder portion 150S may be in an inverse proportion to the line width of the trimmed portion 150P. For example, as the line width of the trimmed portion 150P becomes narrower, the line width of the shoulder portion 150S may be increased.

As the line width of the trimmed portion 150P becomes narrower, the volume of the upper supporter USP disposed between the trimmed portions 150P may be increased, thus increasing the supporting force of the supporter. For example, as the line width of the trimmed portion 150P becomes narrower, the line width of the shoulder portion 150S may be increased, which may eventually increase the contact area between a dielectric layer 151 and the lower electrode 150 and increase the capacitance.

The lower and upper supporters 140 and USP may be disposed over the substrate 101. The lower and upper supporters 140 and USP may be spaced apart from each other in a direction perpendicular to the upper surface of the substrate 101. The number of the lower supporters 140 may be increased or decreased as needed. When a plurality of lower supporters are included, the individual lower supporters 140 may be disposed spaced apart from each other by a predetermined distance in a direction perpendicular to the surface of the substrate 101.

The lower supporter 140 may be disposed between the lower electrodes 150. To be specific, the lower supporter 140 may be disposed between the non-trimmed portions of the lower electrodes 150. The lower supporter 140 may contact the side of the non-trimmed portion of each lower electrode 150 and may surround the side of the non-trimmed portion of each lower electrode 150. The lower supporter 140 may physically support the lower electrodes 150. The lower supporter 140 may contact the side wall of the neighboring lower electrodes 150. The upper supporter USP may be thicker than the lower supporter 140.

The lower supporter 140 may include a dielectric material. For example, the lower supporter 140 may include silicon nitride or silicon carbonitride, however the technical concepts and scope of the present disclosure are not limited thereto.

The upper supporter USP may be formed in multiple layers. The upper supporter USP may be disposed between the neighboring lower electrodes 150 and over the lower electrodes 150. In particular, according to an embodiment of the present disclosure, the upper supporter USP may be disposed between the lower electrode trimmed portions 150P and over the lower electrode trimmed portions 150P. The upper supporter USP may cover a portion of a side of each of the lower electrode trimmed portions 150P. In a direction perpendicular to the surface of the substrate 101, the bottom surface of the upper supporter USP may be spaced apart from the non-trimmed portion of the lower electrode 150 by a predetermined distance. The bottom surface of the upper supporter USP may be disposed at a higher level than the upper surface of the non-trimmed portion of the lower electrode 150, that is, the lower electrode shoulder portion 150S.

The upper supporter USP may include a stacked structure of a supporter liner 141, a first upper supporter 142, and a second upper supporter 143. The supporter liner 141 may cover an upper surface of each lower electrode trimmed portion 150P and a portion of a side of the lower electrode trimmed portion 150P. The supporter liner 141 may have a liner shape that uniformly covers an upper surface of each lower electrode trimmed portion 150P and a portion of a side of the lower electrode trimmed portion 150P.

The first upper supporter 142 may be disposed over the supporter liner 141. The thickness of the first upper supporter 142 may be thicker than the thickness of the lower electrode trimmed portion 150P that is covered by the supporter liner 141. Therefore, the upper surface of the first upper supporter 142 may be planarized. The second upper supporter 143 may be disposed over the first upper supporter 142.

The supporter liner 141, the first upper supporter 142, and the second upper supporter 143 may include the same dielectric material. For example, the supporter liner 141, the first upper supporter 142, and the second upper supporter 143 may include silicon nitride or silicon carbonitride, however the technical concepts and scope of the present disclosure are not limited thereto. According to another embodiment of the present disclosure, the supporter liner 141, the first upper supporter 142, and the second upper supporter 143 may also include one dielectric material selected from the group including SiOC, SiBN, SiBCN, SiCN, SiON, SiN, Si, and doped SiN. According to another embodiment of the present disclosure, the supporter liner 141, the first upper supporter 142, and the second upper supporter 143 may include different dielectric materials.

The dielectric layer 151 may uniformly cover the outer walls of the lower electrodes 150, and the surfaces of the lower and upper supporters 140 and USP. The dielectric layer 151 may cover the outer wall of each lower electrode 150, a portion of the side wall of the lower electrode trimmed portion 150P, and the lower electrode shoulder portion 150S. According to an embodiment of the present disclosure, the area of the dielectric layer 151 may be increased in proportion to the line width of the lower electrode shoulder portion 150S, and thus the capacitance may be increased.

The dielectric layer 151 may include a high-k material having a higher dielectric constant than that of silicon oxide. The high-k material may include zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 105 may be formed of a composite layer including two or more layers of the aforementioned high-k materials. According to an embodiment of the present disclosure, the dielectric layer 151 may be formed of a zirconium oxide-based material having excellent leakage current characteristics while sufficiently lowering the equivalent oxide thickness (EOT). For example, the dielectric layer 151 may include one of ZAZ (ZrO₂/Al₂O₃/ZrO₂), TZAZ (TiO₂/ZrO₂/Al₂O₃/ZrO₂), TZAZT (TiO₂/ZrO₂/Al₂O₃/ZrO₂/TiO₂), ZAZT (ZrO₂/Al₂O₃/ZrO₂/TiO₂), TZ (TiO₂/ZrO₂), and ZAZAT (ZrO₂/Al₂O₃/ZrO₂/Al₂O₃/TiO₂). In the dielectric layer stack such as TZAZ, TZAZT, ZAZT, TZ, and ZAZAT, TiO₂ may be replaced with Ta₂O₅. The dielectric layer 151 may be formed by a Chemical Vapor Deposition (CVD) process or an Atomic Layer Deposition (ALD) process having excellent step coverage.

An upper electrode 152 may be formed over the dielectric layer 151. The upper electrode 152 may include a metal-based material. For example, the upper electrode 152 may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), molybdenum nitride (MoN), titanium silicon nitride (TiSiN), or a combination thereof. The upper electrode 152 may be formed by a Low-Pressure Chemical Vapor Deposition (LPCVD) process, a Plasma Enhanced Chemical Vapor Deposition (PECVD) process, or an Atomic Layer Deposition (ALD) process. According to an embodiment of the present disclosure, the upper electrode 152 may include titanium nitride (ALD-TiN) that is formed by the atomic layer deposition process.

According to another embodiment of the present disclosure, the upper electrode 152 may have a multi-layer structure. The upper electrode 152 may be formed by sequentially stacking a lower metal-containing layer, a silicon germanium layer, and an upper metal-containing layer. The lower metal-containing layer and the upper metal-containing layer may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. For example, the lower metal-containing layer may be titanium nitride, and the upper metal-containing layer may be WN/W in which tungsten nitride and tungsten are stacked. The silicon germanium layer may be doped with boron.

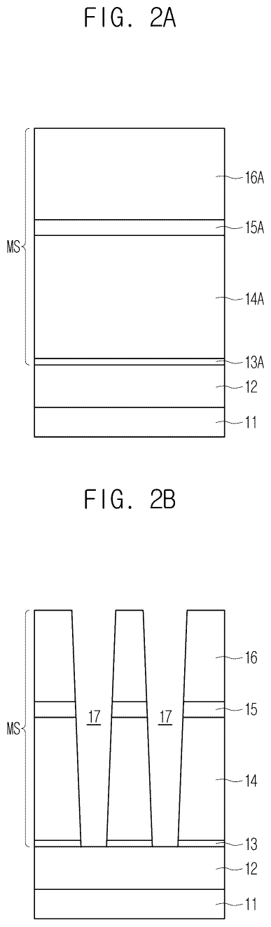

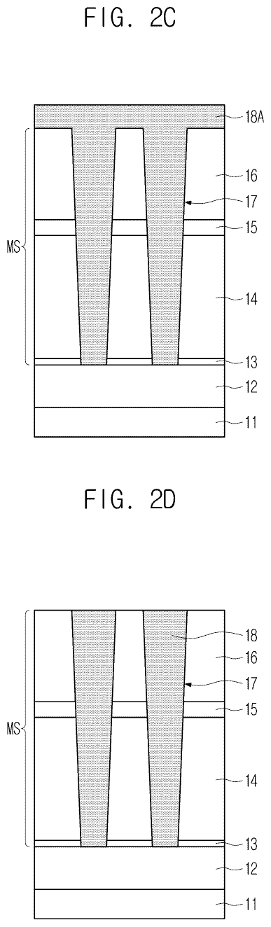

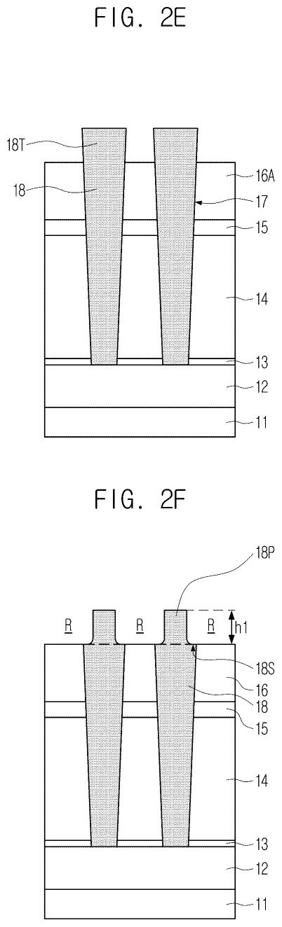

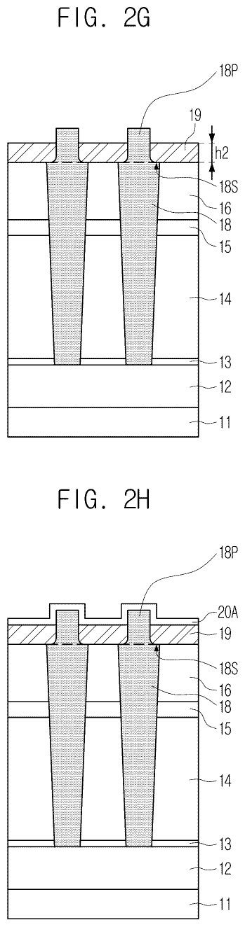

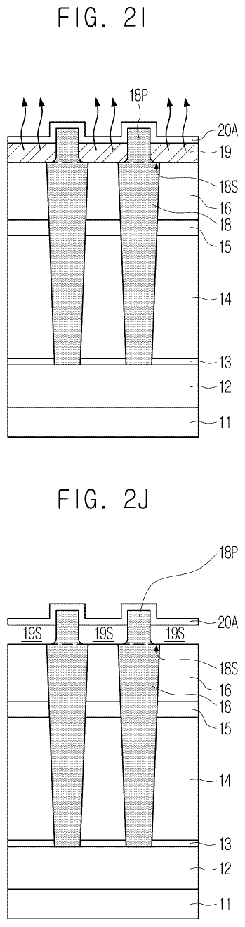

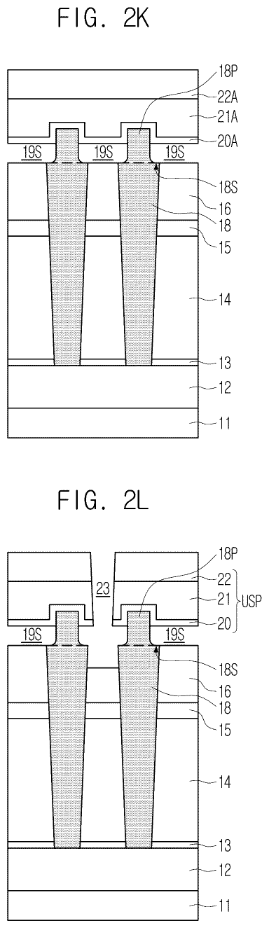

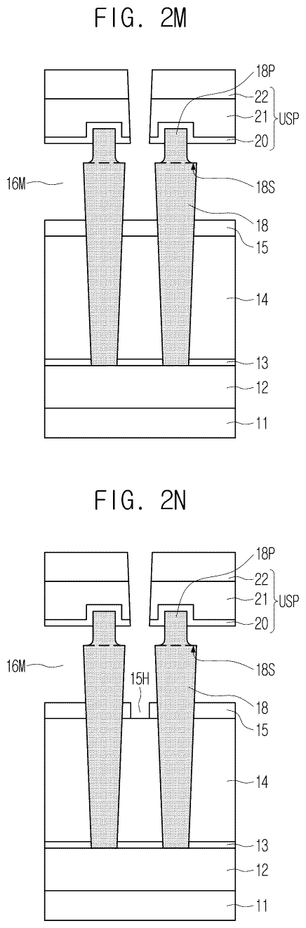

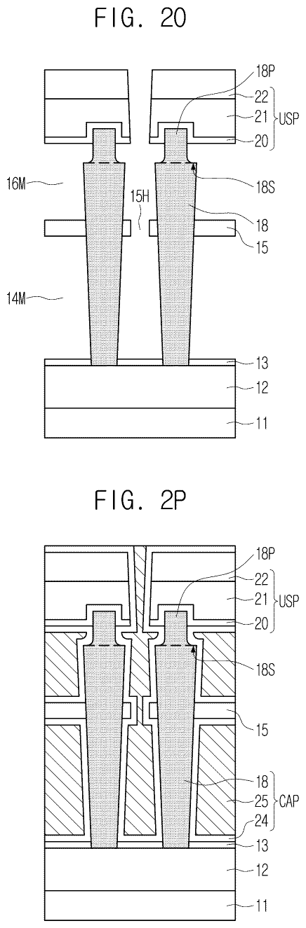

FIGS. 2A to 2P are process cross-sectional views illustrating a method for fabricating a semiconductor device in accordance with an embodiment of the present disclosure. FIGS. 2A to 2P are process cross-sectional views illustrating a method for fabricating the semiconductor device of FIG. 1.

Referring to FIG. 2A, a lower structure 12 may be formed over a substrate 11. The substrate 11 and the lower structure 12 may include the same structure as that of the lower structure LB including the substrate 101 illustrated in FIG. 1. The lower structure 12 may include a gate structure BG disposed in the substrate 101 illustrated in FIG. 1, and a bit line BL, a storage node contact 113, and an inter-layer dielectric layer 112 that are disposed over the substrate 101.

The substrate 11 may be a material appropriate for semiconductor processing. The substrate 11 may include a semiconductor substrate. The substrate 11 may be formed of a material containing silicon. The substrate 11 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 11 may also include another semiconductor material, such as germanium. The substrate 11 may also include a III/V-group semiconductor substrate, for example, a compound semiconductor substrate, such as gallium arsenide (GaAs). The substrate 11 may include an SOI (Silicon-On-Insulator) substrate.

Subsequently, a mold stack MS may be formed over the lower structure 12. The mold stack MS may include a plurality of mold layers 14A and 16A and a lower supporter layer 15A. According to an embodiment of the present disclosure, the mold stack MS may include a stacked structure of an etch stop layer 13A, a first mold layer 14A, a lower supporter layer 15A, and a second mold layer 16A.

The etch stop layer 13A may be used as an etching end point when a storage node hole is formed. The etch stop layer 13A may include a material having an etching selectivity with respect to the first mold layer 14A. The etch stop layer 13A may include a dielectric material. For example, the etch stop layer 13A may include silicon nitride. The etch stop layer 13A may be formed by a Chemical Vapor Deposition (CVD) process, a Physical Vapor Deposition (PVD) process, or an Atomic Layer Deposition (ALD) process. The etch stop layer 13A may also use plasma to increase the deposition effect. That is, the etch stop layer 13A may be formed by a method such as PECVD or PEALD.

The first mold layer 14A, the lower supporter layer 15A, and the second mold layer 16A may serve to provide an opening for forming a lower electrode. According to another embodiment of the present disclosure, the number of the mold layers and the number of the supporter layers may be increased or decreased as needed, such as the height of the storage node hole.

The first and second mold layers 14A and 16A may include a dielectric material. For example, each of the first and second mold layers 14A and 16A may include BSG (Borosilicate Glass), PSG (PhosphoSilicate Glass), BPSG (BoroPhosphoSilicate Glass), or TEOS (Tetra ethyl ortho silicate). Each of the first and second mold layers 14A and 16A may be a single layer. According to another embodiment of the present disclosure, each of the first and second mold layers 14A and 16A may be a multi-layer structure of at least two or more layers. For example, BPSG and TEOS may be stacked. According to another embodiment of the present disclosure, each of the first and second mold layers 14A and 16A may include an undoped silicon layer or an amorphous silicon layer.

The lower supporter layer 15A may include a material having an etching selectivity with respect to the first and second mold layers 14A and 16A. The thickness of the lower supporter layer 15A may be thinner than the thickness of each of the first and second mold layers 14A and 16A. The difficulty of the etching process may be reduced according to the thickness of the lower supporter layer 15A and the thickness of the upper supporter layer to be formed through a subsequent process. For example, as the thickness of the lower supporter layer 15A becomes thinner, the difficulty of the etching process may be reduced. The lower supporter layer 15A may include a nitrogen-containing material. For example, the lower supporter layer 15A may include silicon nitride or silicon carbonitride, however the technical concepts and scope of the present disclosure are not limited thereto.

Referring to FIG. 2B, an opening 17 may be formed. A plurality of openings 17 spaced apart from each other in a horizontal direction parallel to the top surface of the substrate 11 may be formed. The characteristics of the openings 17 will be described by reference to a single opening. Accordingly, the opening 17 may expose a portion of the lower structure 12 by penetrating the mold stack MS. The mold stack MS in which the opening 17 is formed may include a stacked structure of an etch stop pattern 13, a first mold pattern 14, a lower supporter 15, and a second mold pattern 16. The opening 17 may provide an area where a lower electrode is to be formed, and the opening 17 may be referred to as a ‘storage node hole’. The opening 17 may have a negative slope in which the line width becomes narrower as it goes from top to bottom, that is, as it approaches the substrate 11.

To form the opening 17, first a mask pattern may be formed over the second mold layer 16A (see FIG. 2A). Subsequently, the second mold layer 16A (see FIG. 2A), the lower supporter layer 15A (see FIG. 2A), and the first mold layer 14A (see FIG. 2A) may be sequentially etched by using the mask pattern as an etching barrier. Subsequently, the etch stop layer 13A (see FIG. 2A) may be etched to form the opening 17 that exposes the lower structure 12. The lower structure 12 exposed by the opening 17 may be the storage node contact 113 illustrated in FIG. 1.

The opening 17 may have a high aspect ratio. The aspect ratio may refer to the ratio of height to width. According to an embodiment of the present disclosure, the high aspect ratio may refer to a ratio of at least approximately 10:1 or more.

According to an embodiment, the opening 17 may be formed by etching the first and second mold layers 14A and 16A and the lower supporter layer 15A. As a comparative example, when the upper supporter layer is formed in advance over the second mold layer 16A, the etching height may be increased by as much as the height of the upper supporter layer. When the etching height is increased, the etching process margin may be decreased, and accordingly, an opening defect of the opening 17 may occur, or a bowing phenomenon may occur over the opening 17.

However, according to an embodiment, since the upper supporter layer is not applied to the upper portion of the second mold layer 16A at the moment when the opening 17 is formed, the etching burden may be reduced when the opening 17 is formed, and thus, an opening defect or a bowing phenomenon of the opening 17 may be prevented.

Referring to FIG. 2C, a lower electrode material layer 18A may be formed in the opening 17.

The lower electrode material layer 18A may include a metal, a metal nitride, or a combination thereof. For example, the lower electrode material layer 18A may include at least one of titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), and a combination thereof. According to one embodiment of the present disclosure, the lower electrode material layer 18A may include titanium nitride (TiN). The lower electrode material layer 18A may include titanium nitride (ALD-TiN) that is formed by an Atomic Layer Deposition (ALD) process, however the technical concepts and scope of the present disclosure are not limited thereto. According to another embodiment of the present disclosure, the lower electrode material layer 18A may include a stacked structure of TiSiN/TiN.

The lower electrode material layer 18A may be electrically connected to the substrate 11 through the lower structure 12. The lower electrode material layer 18A may be electrically connected to the substrate 11 by the storage node contact 113 illustrated in FIG. 1.

Referring to FIG. 2D, a plurality of lower electrodes 18 may be formed. The lower electrodes 18 may be disposed in the openings 17. The lower electrodes 18 may be formed by an isolation process.

The isolation process may be performed by a polishing process. For example, it may include a Chemical Mechanical Polishing (CMP) process or an etch-back process. The lower electrode material layer 18A (see FIG. 2C) over the second mold pattern 16 may be etched entirely by the isolation process. Therefore, the upper surface of the lower electrode 18 may be disposed at the same level as the upper surface of the second mold pattern 16.

Referring to FIG. 2E, the second mold pattern 16 may be etched to a predetermined height h1 to expose an upper portion 18T of the lower electrode.

The second mold pattern 16 may be etched by an oxide etching process.

Referring to FIG. 2F, lower electrode trimmed portions 18P may be formed separated by recesses R formed between the lower electrode trimmed portions 18P by the etching and trimming processes of the second mold pattern 16.

The lower electrode trimmed portions 18P may be formed by performing a trimming process onto the upper portions 18T (see FIG. 2E) of the lower electrodes exposed by the etching of the second mold pattern 16. The remaining lower electrode 18 onto which the trimming process is not performed may be referred to as a ‘lower portion of the lower electrode’ or a ‘non-trimmed portion’. The line width of each of the trimmed portions 18P may be at least narrower than the line width of the uppermost portion of the non-trimmed portion. The line width of each of the trimmed portions 18P may be adjusted to the minimal line width in a range that bending does not occur. The line width of each of the trimmed portions 18P may be narrower than the line width of the lower surface of the non-trimmed portion, however the technical concepts and scope of the present disclosure are not limited thereto.

The trimmed portions 18P may be disposed at a higher level than the upper surface of the second mold pattern 16. The height of the trimmed portions 18P may be adjusted to the height h1 of a recess of the second mold pattern 16 in FIG. 2E. That is, the height of the trimmed portions 18P may be defined as ‘h1’, which is the etching height of the second mold pattern 16. Each one of the trimmed portions 18P may be continuous with the corresponding one of the non-trimmed portions to form an integrated structure.

As the line width of each of the trimmed portions 18P becomes narrower than the line width of the uppermost portion of the non-trimmed portion, the upper surface of the non-trimmed portion may be partially exposed. Hereinafter, the exposed upper surface of each of the non-trimmed portion may be referred to as the ‘shoulder portion 18S’. The portion where the trimmed portion 18P and the shoulder portion 18S are coupled may be rounded. The line width of the shoulder portion 18S may be adjusted according to the line width of the trimmed portion 18P. The line width of the shoulder portion 18S may be in an inverse proportion to the line width of the trimmed portion 18P. Namely, as the line width of the trimmed portion 18P is decreased, the line width of the shoulder portion 18S may be increased.

Referring to FIG. 2G, a pyrolytic layer 19 surrounding the sides of the trimmed portions 18P may be formed. The pyrolytic layer 19 may gap-fill between the trimmed portions 18P over the second mold pattern 16. The pyrolytic layer 19 may be formed at a height where the upper surface and a portion of the side of the trimmed portions 18P are exposed.

The pyrolytic layer 19 may include a material that is decomposed at a temperature of 500° C. or approximately 500° C. or higher. The pyrolytic layer 19 may be formed between the trimmed portions 18P without a void through a deposition process and a reflow process. For example, after the pyrolytic layer 19 is formed over the second mold pattern 16 and the trimmed portions 18P, the reflow process may be performed in such a manner that the pyrolytic layer 19 gap-fills between the lower electrode trimmed portions 18P without a void. According to another embodiment of the present disclosure, when it is possible to deposit the pyrolytic layer 19 without a void, the reflow process may be omitted.

The pyrolytic layer 19 may include a polymer, i.e., a high molecular weight material. The pyrolytic layer 19 may be deposited at a temperature of approximately 100° C. to 150° C. The reflow process of the pyrolytic layer 19 may be performed at a temperature of approximately 180° C. to 220° C., however the technical concepts and scope of the present disclosure are not limited thereto.

The pyrolytic layer 19 may be adjusted to gap-fill a portion of the thickness h2 between the trimmed portions 18P. Accordingly, the upper surface and a portion of the side of the trimmed portion 18P may be exposed over the pyrolytic layer 19.

Referring to FIG. 2H, a supporter liner layer 20A may be formed conformally over the pyrolytic layer 19 and the trimmed portion 18P.

The supporter liner layer 20A may be formed at a temperature lower than the temperature at which the pyrolytic layer 19 is decomposed. According to an embodiment of the present disclosure, the supporter liner layer 20A may be formed at a temperature of at least approximately 50° C. or lower to prevent the loss that may be caused due to the heat, however the technical concepts and scope of the present disclosure are not limited thereto.

The supporter liner layer 20A may cover the upper portion of the pyrolytic layer 19 and the upper portions and the exposed sides of the trimmed portions 18P. The supporter liner layer 20A may be a liner shape that uniformly covers the profile of the upper portion of the entire structure. The thickness of the supporter liner layer 20A may be thinner than the thickness of each of the pyrolytic layer 19 and the lower supporter 15.

The supporter liner layer 20A may include a dielectric material having an etching selectivity with respect to the pyrolytic layer 19 and the lower electrode 18. For example, the supporter liner layer 20A may include silicon nitride or silicon carbonitride.

Referring to FIG. 2I, a heat treatment may be performed. Therefore, the pyrolytic layer 19 may be decomposed and volatilized. For example, the heat treatment may be performed at a temperature of at least approximately 500° C. or higher. According to an embodiment, the heat treatment may be performed at a temperature of approximately 500° C. to 550° C.

Referring to FIG. 2J, a horizontal level gap 19S may be formed between the supporter liner layer 20A and the second mold pattern 16. The horizontal level gap 19S may be formed as the pyrolytic layer 19 is removed by the heat treatment illustrated in FIG. 2I.

The supporter liner layer 20A and the non-trimmed portions may be spaced apart from each other by the horizontal level gap 19S. Also, the horizontal level gap 19S may expose a portion of the side wall of each of the trimmed portions 18P and the shoulder portions 18S.

Referring to FIG. 2K, a first upper supporter layer 21A and a second upper supporter layer 22A may be sequentially formed over the supporter liner layer 20A. The first and second upper supporter layers 21A and 22A may include a material having an etching selectivity with respect to the first and second mold patterns 14 and 16. The first and second upper supporter layers 21A and 22A may include a dielectric material. For example, the first and second upper supporter layers 21A and 22A may include silicon nitride or silicon carbonitride, however the technical concepts and scope of the present disclosure are not limited thereto.

The first upper supporter layer 21A may be formed over the supporter liner layer 20A. The first upper supporter layer 21A may be formed with a thickness that is sufficient to gap-fill between the trimmed portions 18P. The thickness of the first upper supporter layer 21A may be thicker than the thickness of the trimmed portion 18P that is covered by the supporter liner layer 20A. The first upper supporter layer 21A may also be formed between the trimmed portions 18P and in an area overlapping with the upper portion of the trimmed portion 18P.

The second upper supporter layer 22A may be formed over the first upper supporter layer 21A. The first and second upper supporter layers 21A and 22A may be formed of the same material. According to another embodiment of the present disclosure, the first and second upper supporter layers 21A and 22A may be formed of different materials.

According to an embodiment, referring to FIG. 2F, by forming the trimmed portion 18P whose line width becomes narrow due to a trimming process, the area (or volume) of the first upper supporter layer 21A gap-filling between the lower electrodes 18 may be increased. Accordingly, the supporting force of the supporter may be increased.

Referring to FIG. 2L, an upper supporter USP including an upper supporter hole 23 may be formed. The upper supporter hole 23 may be formed through a series of processes including forming a mask pattern over the second upper supporter layer 22A, and then sequentially etching the second upper supporter layer 22A, the first upper supporter layer 21A, and the supporter liner layer 20A illustrated in FIG. 2K by using the mask pattern as an etching barrier.

When the upper supporter hole 23 is formed, an exposed portion of the second mold pattern 16 may be lost, however the technical concepts and scope of the present disclosure are not limited thereto.

The upper supporter hole 23 may be formed in a circular, oval, or polygonal shape. The upper supporter hole 23 may be disposed between the lower electrodes 18. According to an embodiment of the present disclosure, the neighboring lower electrodes 18 may share one upper supporter hole 23.

According to an embodiment of the present disclosure, referring to FIG. 2F, by forming the trimmed portion 18P, the process difficulty in forming the upper supporter hole 23 may be reduced. That is, as the gap between the trimmed portions 18P is widened due to the trimming process, the patterning difficulty and the etching difficulty of the mask process for forming the upper supporter hole 23 may be reduced.

The horizontal level gap 19S and the second mold pattern 16 may be exposed by the upper supporter hole 23.

Referring to FIG. 2M, the second mold pattern 16 (see FIG. 2L) may be removed.

The second mold pattern 16 may be removed by a wet dip-out process. The wet chemical for removing the second mold pattern 16 may be supplied through the upper supporter hole 23. The wet chemical may include a wet chemical for removing an oxide. For example, one or more chemicals such as HF, NH₄F/NH₄OH, H₂O₂, HCl, HNO₃, H₂SO₄, and the like may be used as the wet chemical.

When the second mold pattern 16 is removed, the upper supporter USP having an etching selectivity with respect to the wet chemical may not be removed but may remain as it is. As the second mold pattern 16 is removed, a second mold gap 16M exposing a portion of the outer wall of the lower electrode 18 may be formed.

As the surface oxide layer of the lower electrode 18 is removed during the wet dip-out process, the line width of the lower electrode 18 may be decreased.

Referring to FIG. 2N, a lower supporter hole 15H may be formed. The lower supporter hole 15H may be formed to facilitate removing the first mold pattern 14. The lower supporter hole 15H may open an area having the same cross-sectional area as the upper supporter hole 23. The lower supporter hole 15H may be formed by etching the lower supporter 15 that is exposed by the second mold gap 16M.

Referring to FIG. 2O, the first mold pattern 14 (see FIG. 2N) may be removed.

The first mold pattern 14 may be removed by a wet dip-out process. The wet chemical for removing the first mold pattern 14 may be supplied through the lower supporter hole 15H. The wet chemical may include a wet chemical that is suitable for removing an oxide, such as, for example, HF, NH₄F/NH₄OH, H₂O₂, HCl, HNO₃, H₂SO₄, and the like.

When the second mold pattern 16 is removed, the lower supporter 15 and the upper supporter USP having an etching selectivity with respect to the wet chemical may not be removed but may remain substantially intact as they are. As the first mold pattern 14 is removed, a first mold gap 14M exposing the outer wall of the lower electrode 18 may be formed.

As the surface oxide layer of the lower electrode 18 is removed during the wet dip-out process, the line width of the lower electrode 18 may be decreased.

The outer wall of the lower electrode 18 may be exposed by the first and second mold gaps 14M and 16M and the horizontal level gap 19S. All the outer walls of the lower electrode 18 may be exposed except for the area overlapping with the lower and upper supporters 15 and USP. The lower electrode 18 may be supported by the lower and upper supporters 15 and USP, and therefore, the structural stability of the lower electrode 18 is improved and is prevented from collapsing. Furthermore, according to an embodiment, since the trimmed portion 18P with a reduced line width is formed over the lower electrode through a trimming process, the volume of the upper supporter USP disposed between the trimmed portions 18P may be increased. Therefore, the supporting force of the supporter may be increased.

Referring to FIG. 2P, a dielectric layer 24 may be formed over the lower electrode 18, the lower supporter 15, and the upper supporter USP. A portion of the dielectric layer 24 may cover the etch stop pattern 13. The dielectric layer 24 may uniformly cover the outer wall s of the lower electrodes 18, and the surfaces of the lower and upper supporters 15 and USP. The dielectric layer 24 may cover the outer walls of the lower electrode 18, a portion of the side wall of the trimmed portion 18P, and the shoulder portion 18S. Accordingly, the area of the dielectric layer 24 may be increased in proportion to the line width of the shoulder portion 18S, and thus the capacitance may be increased.

The dielectric layer 24 may include a high-k material having a higher dielectric constant than silicon oxide. The high-k material may include zirconium oxide (ZrO₂), aluminum oxide (Al₂O₃), titanium oxide (TiO₂), tantalum oxide (Ta₂O₅), niobium oxide (Nb₂O₅), or strontium titanium oxide (SrTiO₃). According to another embodiment of the present disclosure, the dielectric layer 24 may be formed of a composite layer including two or more layers of the aforementioned high-k materials. According to an embodiment of the present disclosure, the dielectric layer 24 may be formed of a zirconium oxide-based material having excellent leakage current characteristics while sufficiently lowering the equivalent oxide thickness (EOT). For example, the dielectric layer 24 may include one of ZAZ (ZrO₂/Al₂O₃/ZrO₂), TZAZ (TiO₂/ZrO₂/Al₂O₃/ZrO₂), TZAZT (TiO₂/ZrO₂/Al₂O₃/ZrO₂/TiO₂), ZAZT (ZrO₂/Al₂O₃/ZrO₂/TiO₂), TZ (TiO₂/ZrO₂), and ZAZAT (ZrO₂/Al₂O₃/ZrO₂/Al₂O₃/TiO₂). In the dielectric layer stacks such as TZAZ, TZAZT, ZAZT, TZ, and ZAZAT, TiO₂ may be replaced with Ta₂O₅. The dielectric layer 24 may be formed by a Chemical Vapor Deposition (CVD) process or an Atomic Layer Deposition (ALD) process having excellent step coverage.

An upper electrode 25 may be formed over the dielectric layer 24. The upper electrode 25 may include a metal-based material. For example, the upper electrode 25 may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), molybdenum nitride (MoN), titanium silicon nitride (TiSiN), or a combination thereof. The upper electrode 25 may be formed by a Low-Pressure Chemical Vapor Deposition (LPCVD) process, a Plasma Enhanced Chemical Vapor Deposition (PECVD) process, or an Atomic Layer Deposition (ALD) process. According to one embodiment of the present disclosure, the upper electrode 25 may include titanium nitride (ALD-TiN) that is formed by an atomic layer deposition process.

According to another embodiment of the present disclosure, the upper electrode 25 may have a multi-layer structure. The upper electrode 25 may be formed by sequentially stacking a lower metal-containing layer, a silicon germanium layer, and an upper metal-containing layer. The lower metal-containing layer and the upper metal-containing layer may include titanium (Ti), titanium nitride (TiN), tantalum (Ta), tantalum nitride (TaN), titanium aluminum nitride (TiAlN), tungsten (W), tungsten nitride (WN), ruthenium (Ru), ruthenium oxide (RuO₂), iridium (Ir), iridium oxide (IrO₂), platinum (Pt), or a combination thereof. For example, the lower metal-containing layer may be titanium nitride, and the upper metal-containing layer may be WN/W in which tungsten nitride and tungsten are stacked. The silicon germanium layer may be doped with boron. In order to form the upper electrode 25, a process of depositing an upper electrode layer (not shown) and a process of patterning the upper electrode may be performed.

According to an embodiment of the present disclosure, it is possible to increase capacitance by applying a pyrolytic polymer.

According to an embodiment of the present disclosure, it is possible to reduce process difficulty and increase the reliability of a semiconductor by applying an upper supporter after a lower electrode is formed.

While the embodiments of the present disclosure have been described with respect to specific embodiments, it will be apparent to those skilled in the art that various other changes and modifications may be made without departing from the technical concepts and scope of the present disclosure as defined in the following claims. Furthermore, the embodiments may be combined to form additional embodiments.

What is claimed is:

1. A method for fabricating a semiconductor device, the method comprising:
forming a mold stack including a plurality of mold layers and a lower supporter layer over a substrate;
forming a plurality of lower electrodes having lower portions and upper portions in the mold stack;
exposing the upper portions of the lower electrodes by recessing an upper surface of the mold stack;
forming trimmed portions by trimming the exposed upper portions of the lower electrodes;
forming a pyrolytic layer surrounding lower sides of the trimmed portions;
forming a supporter liner layer over the pyrolytic layer and the trimmed portions;
forming a horizontal level gap exposing outer walls of the trimmed portions by removing the pyrolytic layer;
forming an upper supporter layer over the supporter liner layer;
forming a supporter hole exposing the horizontal level gap by etching the upper supporter layer and the supporter liner layer; and
exposing the outer walls of the lower portions of the lower electrodes by removing the mold layers through the supporter hole and the horizontal level gap.

2. The method of claim 1, wherein forming the pyrolytic layer includes:
depositing a pyrolytic layer over the mold stack and the trimmed portions; and
performing a reflow process.

3. The method of claim 1, wherein the pyrolytic layer includes a polymer material that is pyrolyzed at a temperature of at least approximately 500°C. or higher.

4. The method of claim 2, wherein depositing the pyrolytic layer is performed at a temperature of approximately 100°C. to 150°C.

5. The method of claim 2, wherein the reflow process is performed at a temperature of approximately 180°C. to 220°C.

6. The method of claim 1, wherein removing the pyrolytic layer is performed by a heat treatment.

7. The method of claim 6, wherein the heat treatment is performed at a temperature of approximately 500°C. to 550°C.

8. The method of claim 1, wherein forming the mold stack includes sequentially forming a first mold layer, a lower supporter layer, and a second mold layer over the substrate.

9. The method of claim 1, wherein forming the lower electrodes includes:
forming an opening that exposes a portion of the substrate by etching the mold stack;
forming a lower electrode material layer that gap-fills the opening; and
performing an isolation process onto the lower electrode material layer.

10. The method of claim 8, wherein exposing the outer walls of the lower portions of the lower electrodes by removing the mold layers through the supporter hole and the horizontal level gap includes:
removing the second mold layer;
forming a lower supporter hole by etching the lower supporter layer; and
removing the first mold layer.

11. The method of claim 10, wherein removing the second mold layer and removing the first mold layer are performed by a wet dip-out process.

12. The method of claim 1, wherein exposing the outer walls of the lower portions of the lower electrodes by removing the mold layers through the supporter hole and the horizontal level gap includes:
removing the second mold layer;
forming a lower supporter hole by etching the lower supporter layer; and
removing the first mold layer.

13. The method of claim 1, further comprising:
after exposing the outer walls of the lower portions of the lower electrodes,
forming a dielectric layer along the outer walls of the lower electrodes; and
forming an upper electrode over the dielectric layer.

14. A method for fabricating a semiconductor device, the method comprising:
forming a mold stack including a lower supporter layer over a substrate;
forming a lower electrode in the mold stack;
exposing an upper portion of the lower electrode;
trimming the exposed upper portion of the lower electrodes to form a trimmed portion of the lower electrode exposed over the mold stack;
surrounding lower sides of the trimmed portion with a pyrolytic layer;
forming a supporter liner layer surrounding a top surface of the trimmed portion of the lower electrode and the pyrolytic layer; and
forming an upper supporter layer over the supporter liner layer.
